(19) United States
(12) Patent Application Publication
(10) Pub. No.: US 2024/0030360 A1
(43) Pub. Date: Jan. 25, 2024

(54) PHOTODIODE DEVICE WITH HIGH RESPONSIVITY

(71) Applicant: ams-Osram AG, PREMSTÄTTEN (AT)

(72) Inventors: Gerald Meinhardt, GRAZ (AT); Frederic Roger, GRAZ (AT); Ingrid Jonak-Auer, GRAZ (AT); Eugene G. Dierschke, DALLAS, TX (US)

(73) Assignee: ams-Osram AG, PREMSTÄTTEN (AT)

(21) Appl. No.: 18/256,455

(22) PCT Filed: Nov. 29, 2021
(86) PCT No.: PCT/EP2021/083385

§ 371 Date: Jun. 8, 2023

(30) Foreign Application Priority Data
Dec. 11, 2020 (DE) 10 2020 133 180.0

(51) Int. Cl. H01L 31/0216; H01L 27/146; H01L 31/102

(52) U.S. Cl. CPC H01L 31/02161; H01L 27/14645; H01L 31/102; H01L 27/1463

(57) ABSTRACT

A photodiode device includes a semiconductor substrate with a main surface, the semiconductor substrate being of a first type of electric conductivity. At least one doped well of a second type of electric conductivity is arranged at the main surface of the substrate, the second type of electric conductivity being opposite to the first type of electric conductivity. The at least one doped well and the substrate are electrically contactable. A cover layer is arranged on the main surface of the substrate. The cover layer is at least one of an epi-layer of the first type of electric conductivity and a dielectric surface passivation layer comprising a plurality of space charges, or a combination thereof.

### CROSS-REFERENCE TO RELATED APPLICATIONS

The present application is a national stage entry from International Application No. PCT/EP2021/083385, filed on Nov. 29, 2021, published as International Publication No. WO 2022/122451 A1 on Jun. 16, 2022, and claims priority to German Patent Application No. 10 2020 133 180.0, filed Dec. 11, 2020, the disclosures of all of which are hereby incorporated by reference in their entireties.

### FIELD OF DISCLOSURE

The invention relates to a photodiode device and an optoelectronic system.

### BACKGROUND OF THE INVENTION

There is an increasing demand for photodetectors with high sensitivity and spectral responsivity. Especially for photodetectors fabricated according to standard CMOS technologies, the working principle is the conversion of optical intensity into a photocurrent or a voltage using photodiodes. Electromagnetic radiation enters the photodiode substrate and generates charge carriers, i.e. electron-hole pairs. However, the penetration depth of the electromagnetic radiation depends on its wavelength. Light of short wavelengths, in particular light in the blue wavelength range, penetrates the substrate only a few nanometers. The charge carriers generated there, but also charge carrier diffusing towards the surface, can easily recombine and thus do not contribute to the photocurrent. Conventional photodiode devices therefore suffer from low responsivity, especially in the blue spectral range of wavelengths.

Moreover, the photodiodes can be connected with a CMOS circuit by wafer-to-wafer bonding, by flip-chip assembly of semiconductor chips, or by monolithic integration of CMOS components and photodiodes in the same semiconductor device. Apart from being a very cost-effective solution, a monolithic integration provides the best interconnection between the photodiodes and the CMOS circuitry. However, semiconductor materials that are suitable for CMOS circuits may cause difficulties in integrating photodiodes with respect to leakage, capacitance, sensitivity, spectral responsivity, response time, and radiation hardness.

It is an objective to provide an improved concept for a photodiode device with high responsivity and overcoming the above mentioned drawbacks. It is further an objective to provide an electronic system comprising a photodiode device with high responsivity.

This object is achieved with the photodiode device according to the independent claim. Embodiments derive from the dependent claims.

### SUMMARY OF THE INVENTION

In an embodiment a photodiode device comprises a semiconductor substrate with a main surface, the semiconductor substrate being of a first type of electric conductivity. At least one doped well of a second type of electric conductivity is arranged at the main surface of the substrate, the second type of electric conductivity being opposite to the first type of electric conductivity. The doped wells and the substrate are electrically contactable. The photodiode device further comprises a cover layer being arranged on the main surface of the substrate. The cover layer is at least one of an epi-layer of the first type of electric conductivity and a dielectric surface passivation layer comprising a plurality of space charges, or a combination thereof.

This can mean that the cover layer is an epi-layer of the first type of electric conductivity. Alternatively, the cover layer is a dielectric surface passivation layer comprising a plurality of space charges. Alternatively, the cover layer is a combination of an epi-layer and a dielectric surface passivation layer.

The semiconductor substrate has a main plane of extension. The main surface of the semiconductor substrate runs parallel to the main plane of extension. The semiconductor substrate comprises, for example, silicon. The semiconductor substrate may have a base doping, in particular a base doping of the first type of electric conductivity. For example, the first type of electric conductivity is p-type and the second type of electric conductivity is n-type, or vice versa.

In a preferred embodiment the semiconductor substrate comprises a higher doped semiconductor body and a lower doped device layer, which is epitaxially grown on the semiconductor body. The main surface may be formed by the device layer. This means that in a transversal direction the device layer is arranged above the semiconductor body. The transversal direction runs perpendicular to the main plane of extension of the substrate.

The at least one doped well is arranged at the main surface of the substrate. The doped well forms a pn-junction with the substrate. In particular, the doped well may be formed within the device layer. The doped well has an extent in lateral directions, wherein lateral directions run parallel to the main plane of extension of the substrate. The doped well also has an extent in the transversal directions. The doped well comprises an upper surface, which is arranged at the main surface of the substrate. This means that the upper surface of the doped well is on a same level as the main surface and forms a part of the main surface. The doped well reaches from the main surface of the substrate to a certain depth into the substrate. This can mean that the doped well is embedded in the device layer of the semiconductor substrate. The photodiode device may comprise more than one doped well. In that case, the doped wells are spaced apart from each other at the main surface of the substrate.

The at least one doped well and the substrate can be contacted electrically. In case that the doped wells are n-type, an electric contact contacting the doped well forms a cathode terminal. Accordingly, an electric contact contacting the substrate, which is p-type in this case, forms an anode terminal. As mentioned above, the type of electric conductivity of the doped wells and the substrate can be vice versa. In case that more than one doped well is present, the doped wells can be electrically connected in parallel with each other. For example, at least some of the doped wells are electrically connected in parallel with each other.

A contact region may be arranged at the upper surface of the doped well. The contact region has the same type of electric conductivity as the doped well, but its doping concentration is higher. The contact region enables the formation of an Ohmic contact to the respective doped well.

Correspondingly, a further contact region may be arranged on the main surface of the substrate. The further contact region has the same type of electric conductivity as the substrate, but its doping concentration is higher. The further contact region enables the formation of an Ohmic contact to the substrate. Alternatively, the substrate may be electrically contacted from a rear side of the substrate.

The cover layer is arranged on the main surface of the substrate at least in places. In case that the cover layer is an epi-layer, the epi-layer may be epitaxially grown on the main surface of the substrate. The epi-layer can cover the entire main surface that is not covered by the at least one doped well. This means that in the transversal direction a region above the at least one doped well is free from the epi-layer. In lateral directions the epi-layer may have a distance to the at least one doped well. However, the epi-layer may also be adjacent to the at least one doped well in lateral direction. That the epi-layer slightly overlaps the at least one doped well is likewise possible.

In case that the cover layer is a dielectric surface passivation layer, the dielectric surface passivation layer may cover the entire main surface including the at least one doped well. However, that the dielectric surface passivation layer does not cover the doped well is likewise possible. In this case, a region above the at least one doped well is free from the dielectric surface passivation layer. The dielectric surface passivation layer may be spaced from the at least one doped well in lateral directions. A thin native oxide film may be arranged between the main surface and the dielectric surface passivation layer.

It is further possible that both the epi-layer and the dielectric surface passivation layer are comprised by the cover layer. This means that the cover layer may be arranged on the main surface at least in places outside the doped well. The epi-layer and the dielectric surface passivation layer can be arranged on top of each other in the transversal direction. The dielectric surface passivation layer can be arranged on top of the epi-layer. The arrangements described above, in particular with regard to the doped well, do also apply in this specific configuration. For example, the underlying epi-layer may be spaced from the doped well, while the overlying dielectric surface passivation covers the doped well. This means that in places the cover layer may be formed as a stack of both the epi-layer and the dielectric surface passivation layer, while in other places the cover layer may be formed by only one of both layers.

The photodiode device is provided to convert electromagnetic radiation into an electric signal. When photons of sufficient energy hit the main surface of the photodiode device, charge carriers, i.e. electron-hole pairs, are generated. The charge carriers drift towards the respective electric terminals. This can lead to a photocurrent. The photodiode device can be monolithically integrated into a CMOS-integrated circuit. The monolithic integration offers huge advantages over a discrete solution consisting of a discrete photodiode array and a discrete ASIC, namely yield, costs and performance.

The epi-layer and/or the dielectric surface passivation layer lead to increased spectral responsivity of the photodiode device for the following reasons:

The doping concentration of the epi-layer can be higher than the doping concentration of the device layer of the substrate. Due to the doping gradient photo-induced minority charge carriers are repelled away from the interface. Therefore, the photo-induced charge carriers are prevented from recombining at the main surface and can contribute to the photocurrent. The spectral responsivity of the photodiode device is therefore enhanced.

The space charges comprised by the dielectric surface passivation layer result in an electric field at the main surface of the substrate. Due to the electric field photo-induced minority charge carriers are repelled away from the interface, such that recombination processes are prevented. Moreover, surface recombination velocities are reduced due to the dielectric surface passivation layer. Thus, the minority charge carriers can contribute to the photocurrent. The spectral responsivity of the photodiode device is therefore enhanced. Additionally, the dielectric surface passivation layer can additionally be used as anti-reflective coating (ARC), such that reflection of incident electromagnetic radiation is avoided.

Additionally, the epi-layer can be configured to protect the underlying layers. The epi-layer can be provided for radiation hardness of the photodiode device. For example, the epi-layer prevents degradation of the photodiode device if exposed to X-radiation.

In some embodiments, the substrate comprises a semiconductor body and a device layer arranged on the semiconductor body, such that the main surface is formed by a surface of the device layer. As mentioned above, the semiconductor body may have a higher doping concentration than the device layer. The device layer is epitaxially grown on the semiconductor body. The high doping concentration of the semiconductor body ensures low electrical resistivity of the substrate. On the other hand, the doping concentration of the semiconductor body may be too high for integrating electronic components, such as an optional integrated circuit, on its surface. Therefore, the device layer is arranged on top of the semiconductor body. The doping concentration of the device layer can be chosen such that it is suitable for integrating the photodiode and optional circuitry at the main surface.

In some embodiments, where the cover layer comprises the epi-layer, the epi-layer is in-situ doped for the first type of electric conductivity, such that it has a doping concentration that is higher than the doping concentration of the device layer.

As mentioned above, the epi-layer is epitaxially grown on the main surface of the substrate. During production, i.e. during the epitaxy process, the substrate is exposed to a dopant, e.g. boron. In this way, the dopant is incorporated into the crystal lattice of the epi-layer. As the epi-layer is in-situ doped but not doped by ion implantation, the crystal damage at the main surface of the semiconductor substrate is low and end-of-range defects caused by ion implantation are avoided. Compared to ion implant doping, this leads to reduced leakage currents and higher responsivity, in particular in the blue spectral range.

The doping concentration of the epi-layer is higher than the doping concentration of the device layer. Due to the doping gradient photo-induced minority charge carriers are repelled away from the interface. Due to the higher doping the Fermi level is closer to the edge of the valence band, which increases the energy barrier for the minority charge carriers diffusing towards the main surface. Therefore, the photo-induced charge carriers are prevented from recombining at the main surface and can contribute to the photocurrent. The spectral responsivity of the photodiode device is therefore enhanced.

The in-situ doped epi-layer may have a doping concentration that is lower than a doping concentration of a typical doped surface region generated by ion implantation. Moreover, the junction depth can be shallower. These factors lead to an increased recombination lifetime of the charge carriers. In particular, Auger recombination is reduced, as Auger recombination is the more probable, the higher the doping. This is in turn leads to a high responsivity, as the charge carriers can contribute to the photocurrent.

In some embodiments, the epi-layer has a thickness being at most 100 nm. In some other embodiments, the epi-layer has a thickness being at most 50 nm. Alternatively, the thickness of the epi-layer is at most 10 nm. The thickness of the epi-layer can be as thin as technically possible. By having a small thickness, electromagnetic radiation, in particular in the blue spectral range, can enter the substrate more deeply, such that charge carriers are generated in deeper regions of the substrate. As the epi-layer is epitaxially grown, its thickness can be controlled very accurately. Advantageously, this leads to less process variability and better reliability of the photodiode device.

In some embodiments, where the cover layer comprises the dielectric surface passivation, the dielectric surface passivation layer comprises positive space charges. Alternatively, the dielectric surface passivation layer comprises negative space charges.

Due the space charges an electric field is established at the main surface of the substrate. Due to the space charges, an inversion layer or an accumulation layer is formed at the main surface of the substrate. The accumulation layer or the inversion layer, respectively, are formed at the interface to the dielectric surface passivation layer.

Whether an accumulation layer or an inversion layer is formed at the main surface of the substrate depends on the type of electric conductivity of the substrate. If the substrate is p-type and the dielectric surface passivation layer comprises negative space charges, an accumulation layer is formed. Majority charge carriers, in this case holes, are attracted by the negative space charges, such that they accumulate at the main surface. Accordingly, if the substrate is n-type, holes are minority charge carriers, so that an inversion layer is formed at the main surface.

If the substrate is p-type and the dielectric surface passivation layer comprises positive space charges, an inversion layer is formed. Minority charge carriers, in this case electrons, are attracted by the positive space charges, so that an inversion layer is formed at the main surface. Accordingly, if the substrate is n-type, electrons are majority charge carriers and an accumulation layer is formed at the main surface.

Both accumulation layer and inversion layer are suitable to passivate the main surface of the substrate. This can mean that charge carriers cannot recombine at the main surface. For example, if an inversion layer is formed by an excess of electrons at the main surface, photo-induced electrons diffusing towards the main surface will not find holes to recombine because they are already saturated by the excess of electrons. Due to the surplus of electrons they will diffuse away from the main surface again. If an accumulation layer is formed by an excess of holes at the main surface, the conduction band is bending upwards, such that minority charge carriers would have to overcome a higher energy barrier. This is sometimes called electron rejection boundary condition.

In other words, the electric field caused by the space charges within the dielectric surface passivation layer results in repelling of minority charge carriers away from the main surface or the interface, respectively. This leads to a high responsivity, as the charge carriers can contribute to the photocurrent. Moreover, the surface recombination velocities at the interface between the main surface of the substrate and the dielectric surface passivation layer are low, as the surface states are saturated. This in turn leads to low leakage currents.

In some embodiments, comprises the dielectric surface passivation layer comprises silicon nitride (SiN). For example, the dielectric surface passivation layer comprises at least one of SiN or non-stoichiometric Si₃₊ₓN₄₋ₓ. With these materials positive space charges can be formed in the dielectric surface passivation layer. In some other embodiments, the dielectric surface passivation layer comprises aluminum oxide (Al₂O₃) and/or hafnium oxide (HfO₂). With these materials negative space charges can be formed in the dielectric surface passivation layer. In both ways, an electric field is established at the main surface of the substrate.

In the transversal direction the dielectric surface passivation layer can have a thickness of less than 100 nm. For example, the thickness of the dielectric surface passivation layer is less than 50 nm. Additionally, the thickness of the dielectric surface passivation layer can be controlled very accurately so that the process variability is decreased and the reliability of the photodiode device is increased.

In some embodiments, the epi-layer is arranged such that in the transversal direction a region above the at least one doped well is free from the epi-layer. The epi-layer can cover the entire main surface that is not covered by the at least one doped well. In lateral directions the epi-layer may have a distance to the at least one doped well or the epi-layer may be adjacent to the at least one doped well. That the epi-layer slightly overlaps the at least one doped well is likewise possible.

The epi-layer and the doped well are doped for opposite types of electric conductivity. Due to the arrangement described above a pn-junction formed at the upper surface of the doped well is avoided. Moreover, as the region above the doped well is free from the epi-layer, the doped well can be contacted via the contact region.

In some embodiments, the cover layer is provided for repelling charge carriers and/or for use as anti-reflective coating. As described above, repelling of charge carriers is achieved by either the higher doping of the epi-layer compared to the doping of the device layer, or by the space charges within the dielectric surface passivation layer. Photo-induced charge carriers are therefore prevented from recombining at the main surface and can contribute to the photocurrent. Thus, the spectral responsivity of the photodiode device is enhanced.

Additionally, in case that the cover layer comprises the dielectric surface passivation layer, it can also function as ARC. Therefore, more electromagnetic radiation can reach the substrate in order to generate electron-hole pairs. The photodiode device is more sensitive to electromagnetic radiation, which increases its responsivity.

In some embodiments, the photodiode device further comprises at least one doped surface region of the first type of electric conductivity at the main surface of the substrate. The at least one doped well is free from the doped surface region.

The doped surface region may cover the entire main surface that is not covered by the doped wells. However, the doped surface region may also cover the main surface only in places. In particular, if an epi-layer is present, the doped surface region may be arranged at regions on the main surface not covered by the epi-layer. However, in lateral directions the epi-layer and the doped surface region can also overlap.

The doped surface region is formed within the device layer and has a doping concentration that is higher than the doping concentration of the device layer and/or of the epi-layer. In the transversal direction, the doped surface region extends less into the substrate than the doped wells. If the semiconductor substrate is p-type, the doped surface region is p-type as well, whereas the doped wells are n-type. The doped wells may have a doping concentration which is typical for so-called n-wells in a CMOS fabrication process. However, the doping concentration of the doped region may be typical for source or drain regions of a p-type MOSFET, or lower than in said regions. The doped surface region may be formed by ion implantation.

According to some implementations, the photodiode device avoids the usage of a field-oxide at the main surface of the substrate by means of the doped surface region. In conventional devices, where a field-oxide is used, the speed of the photodiode is impaired by the Fermi-level pinning effect underneath field-oxide regions. This effect is mostly present in p-type semiconductors typically used in standard CMOS processes. By bending the conduction and valence band, respectively, charge carriers are accumulated underneath the field-oxide that translate to a slow turn-on behaviour. This slow response is most pronounced for low current levels. That means that after an excitation pulse the photocurrent remains at the level of the dark current level for several tens of milliseconds until the photodiode eventually produces the desired photocurrent. The same mechanism deteriorates the leading edge of a photocurrent pulse after illumination is turned on, causing decreased sensitivity of the photodetector for several integration periods of an analog-to-digital converter (ADC) readout circuitry.

By applying the doped surface region, which may be a very shallow, highly doped p-type implantation region, these issues are addressed and the response of the photodiode is increased. Furthermore, the doped surface region can provide good radiation tolerance of the device. For example, the doped surface region protects the underlying layers from damage caused by X-rays. Furthermore, minority carriers are repelled away from the main surface due to the doped surface region. Thus, the spectral responsivity of the photodiode device is increased and the leakage currents are decreased. The doped surface region can further be provided to establish a low Ohmic electrical contact to the substrate.

In some embodiments, there is a spacing in lateral directions between the at least one doped well and the at least one doped surface region.

This can mean that the doped surface region is not adjacent to the doped well. In contrast, the doped well and the surface region are separated by the lower doped device layer. By way of example, the spacing between the doped well and the doped surface region is between 0.1 μm and 3 μm. The junction capacitance between the doped well and the doped surface region can be kept low due to the spacing between those components. Therefore, the leakage currents are reduced.

However, the doped surface region may also be adjacent to the doped well. This means that the doped surface region may be in direct contact with the doped well at the main surface of the substrate. In this case the spacing is zero. The doped well forms a pn-junction with the substrate, in particular with the device layer. Thus a space charge region is formed.

The doped surface region being in direct contact with the doped well prevents the space charge region from reaching the main surface of the substrate. This in turn aims to prevent undesired electrical effects at the main surface, such that the electrical characteristics of the photodiode device are optimized.

In some embodiments, the at least one doped surface region forms a ring or a frame surrounding the at least one doped well in lateral directions. This can mean that the doped surface region is arranged at the main surface in a region adjacent to the doped well. For example, the doped surface region is arranged in the region adjacent to the doped well, where otherwise a space charge region would be formed. By way of example, a width of the ring or the frame is at least 0.5 μm and at most 1.5 μm. The width refers to the lateral extent of the doped surface region. Advantageously, the substrate can be contacted via the doped surface region. Therefore, the substrate is contacted in the vicinity of the doped well. This ensures that the substrate has a fixed electric potential, e.g. a ground potential (GND), in the vicinity of the doped well. However, the substrate can also be electrically contacted at a distance from the doped well. For example, the substrate can be electrically contacted at a periphery of the photodiode device.

In some embodiments, the photodiode device further comprises an intermetal dielectric arranged on or above the main surface of the substrate. The intermetal dielectric may comprise silicon oxide. In places, where the epi-layer and/or the dielectric surface passivation layer is present, the intermetal dielectric may be arranged on said layers.

A conductor track is embedded in the intermetal dielectric and electrically connected to the doped well. A further conductor track is embedded in the intermetal dielectric and electrically connected to the substrate. The conductor track and the further conductor track may be formed by metal layers embedded in the intermetal dielectric. The conductor track and the further conductor track may be formed by metal layers of different metallization levels. In this case, the conductor track and the further conductor track may be stacked. However, the conductor track and the further conductor track may also be formed by portions of the same metallization layer. For example, the conductor track and the further conductor track comprise aluminum. Besides of the conductor track and the further conductor track, further metal layers may be arranged within the intermetal dielectric.

The conductor track and the further conductor track may be electrically connected to an optional CMOS circuitry placed aside the photodiode device and/or to electrical contacts for external contacting. The conductor track may be electrically connected to the doped well by means of a contact plug. In particular, the contact plug is arranged on the contact region of the doped well. Accordingly, the further conductor track may be electrically connected to the substrate by means of a further contact plug. In particular, the further contact plug is arranged on the doped surface region or on the epi-layer. The contact plug and the further contact plug may comprise a metal, for example tungsten. Advantageously, the doped well and the substrate can be electrically contacted by means of a conventional CMOS metallization.

In some embodiments, the photodiode device further comprises a trench. The trench extends from the main surface into the substrate. The trench extends from the main surface further into the substrate than the at least one doped well. Moreover, the trench surrounds an area of the main surface including the at least one doped well.

The trench surrounds the area including the doped well without dividing this area. The doped surface region and the epi-layer can cover the main surface surrounded by the trench, apart from the doped well. The dielectric surface passivation layer can cover the entire main surface surrounded by the trench. In the transversal direction, the trench may extend further into the substrate than the doped well. In particular, the trench may extend from the main surface until within the semiconductor body. This means, the trench extends completely through the device layer. The trench can extend through a part of the semiconductor body. This means, the trench does not extend completely through the semiconductor body.

The trench can be provided to prevent diffusion of charge carriers to regions outside the area which is surrounded by the trench. Therefore, crosstalk between neighboring photodiode devices or neighboring pixels of the photodiode device can be prevented. The trench also prevents diffusion of charge carriers into optional circuitry next to the photodiode device. Reduced crosstalk can be in particular achieved, if the trench extends further into the substrate than the doped well.

In some embodiments, the trench is at least partially filled with a doped semiconductor material or an electrically insulating material. A dopant, for example a p-type dopant, can be introduced into sidewalls of the trench. Subsequently, the trench can be filled with an electrically insulating material, for example SiO₂. Alternatively, the trench is completely filled with a doped semiconductor material of the first type of conductivity. The trench or a filling of the trench can be electrically connected to a terminal. For example, the trench or a filling of the trench is electrically connected with the further conductor tracks.

In case that the trench is at least partially filled with a doped semiconductor material of the first type of conductivity, minority charge carriers are repelled from the trench. The minority charge carriers are repelled for the same reasons as mentioned above in conjunction with the epi-layer. Due to this mechanism photo-induced charge carriers are not lost, but can contribute to the photocurrent. Therefore, the responsivity of the photodiode is enhanced.

In some other implementations, the trench is replaced by a guard ring, which is arranged in the substrate surrounding the area including the at least one doped well. The guard ring does not divide or intersect this areas. The guard ring may comprise an optional boundary region and a core region. The boundary region has the same type of conductivity as the doped surface region, and the core region has the opposite type of conductivity. The boundary region and the core region of the guard ring are electrically contactable. In particular, a ground potential (GND) is applied on the guard ring. The guard ring is provided to prevent crosstalk between neighboring photodiode devices and/or pixels of the photodiode device. This has the advantage that photo-induced charge carriers are prevented from diffusing away from the area including the at least one doped well. The trench or the guard ring enable high spectral responsivity and a low leakage current of the photodiode device.

In some embodiments, the at least one doped well is comprised by one pixel of an array of pixels of the photodiode device. The pixels are separated by the trench. Alternatively, the pixels are separated by the guard ring.

This means that in a top-view the pixel corresponds to the area including the at least one doped well that is surrounded by the trench. Each pixel can comprise more than one doped well. The doped wells can be electrically connected in parallel. The pixels can be designed equally. The array of pixels can be provided to generate a digital image with a sufficient resolution according to a light distribution incident on the photodiode device. Crosstalk between neighboring pixels is prevented by means of the trench or the guard ring, respectively. The sensitivity to electromagnetic radiation is large since nearly all charge carriers generated by the electromagnetic radiation within one pixel can be collected by the electric terminals.

According to some implementations, the electromagnetic radiation to be detected is in the infrared wavelength range, in particular in the near-infrared wavelength range. In addition or alternatively, the electromagnetic radiation to be detected is in the visible wavelength range. It is also possible, that the electromagnetic radiation to be detected is in a range overlapping at least two of the infrared, the near-infrared or in the visible wavelength range.

According to some implementations, at least some pixels of the array of pixels are adjusted to a portion of the wavelength spectrum. For example, for adjusting the sensitivity to a certain portion of the spectrum of incident electromagnetic radiation an optical wavelength filter can be arranged between the main surface and a source of the incident electromagnetic radiation.

Furthermore, an optoelectronic system is provided that comprises the photodiode device. This means that all features disclosed for the photodiode device are also disclosed for and applicable to the electronic system and vice-versa.

The electronic system is provided for detection of electromagnetic radiation. In particular, ambient light is to be detected. The optoelectronic system may require a high sensitive photodiode device, which therefore exhibits low leakage and high spectral responsivity.

However, that X-radiation is to be detected is likewise possible. For example, the optoelectronic system is a computed tomography (CT) system. The X-rays are detected via a scintillator that transforms the X-rays into electromagnetic radiation detectable by the photodiode device. For example, the scintillator transforms the X-rays into visible light, which is then detected with the help of an array of photodiode devices. The scintillator may be arranged above the main surface of the substrate or above the intermetal dielectric.

The optoelectronic system may further comprise (CMOS-) circuitry for reading out electrical signals from the photodiode device. For example, for readout purposes the electronic system comprises storage capacitors, memory elements, an analog-to-digital converter (ADC) or the like. The circuitry may be integrated on the same semiconductor substrate as the photodiode device. As such, a monolithic integration of CMOS components and photodiodes in the same semiconductor substrate can be achieved.

Such optoelectronic systems can be conveniently employed in smart phones, tablet computers, laptops, camera modules or CT-applications. Moreover, the electronic system may be used in the wearable segment, or for metrology and spectrometry applications.

### BRIEF DESCRIPTION OF THE DRAWINGS

The following description of figures may further illustrate and explain aspects of the improved concept. Components and parts of the sensor arrangement that are functionally identical or have an identical effect are denoted by identical reference symbols. Identical or effectively identical components and parts might be described only with respect to the figures where they occur first. Their description is not necessarily repeated in successive figures.

FIG. 1 shows a cross-section of an embodiment of a photodiode device.

FIG. 2 shows a cross-section of another embodiment of a photodiode device.

FIG. 3 shows a cross-section of another embodiment of a photodiode device.

FIG. 4 shows a cross-section of another embodiment of a photodiode device.

FIG. 5 shows a cross-section of another embodiment of a photodiode device.

FIG. 6 shows a cross-section of another embodiment of a photodiode device.

FIG. 7 shows a cross-section of another embodiment of a photodiode device.

FIG. 8 shows a top-view of another embodiment of a photodiode device.

FIG. 9 shows a cross-section of another embodiment of a photodiode device.

FIG. 10 shows a cross-section of another embodiment of a photodiode device.

FIG. 11 shows a top-view of another embodiment of a photodiode device.

FIG. 12 shows a schematic of an optoelectronic system comprising a photodiode device.

### DETAILED DESCRIPTION

In FIG. 1 a cross-section of an embodiment of a photodiode device 1 is shown. The photodiode device comprises a semiconductor substrate 2 with a main surface 3. For example, the semiconductor substrate comprises silicon (Si). The substrate 2 has a main plane of extension. The main surface 3 extend in lateral directions x, y, wherein the lateral directions x, y run parallel to the main plane of extension of the substrate 2. The substrate 2 comprises a highly doped semiconductor body 4 and a lower doped device layer 5. The device layer 5 is arranged in a transversal direction z on top of the semiconductor body 4, wherein the transversal direction z is perpendicular to the main plane of extension of the substrate 2. The main surface 3 is thus formed by the device layer 5. The doping of the substrate 2 is such that the substrate 2 is of a first type of electric conductivity, which is opposite to a second type of electric conductivity. For example, the first type of electric conductivity is p-type.

At the main surface 3 of the substrate 2 at least one doped well 6 is arranged. In the example of FIG. 1 only one doped well 6 is arranged at the main surface 3. The doped well 6 is of the second type of electric conductivity, for example n-type. The doped well 6 has an extent in lateral directions x, y. For example, a lateral extent d, d′ of the doped well 6 is in the range of few micrometer. Furthermore, the doped well 6 extends in the transversal direction z. This means that the doped well 6 reaches from the main surface 3 into the substrate 2. The lateral extent d′ of the doped well 6 at the main surface 3 may be different from its lateral extent d in deeper regions of the substrate 2. For example and as shown in FIG. 1, the doped well 6 can be narrower at the main surface 3. The doped well 6 comprises an upper surface 7. The upper surface 7 is formed by the main surface 3 of the substrate 2. This means that in the transversal direction z the upper surface 7 is on the same level as the main surface 3.

The doped well 6 further comprises a contact region 8 placed at the upper surface 7 of the doped well 6. The contact region 8 has the same type of electric conductivity as the doped well 6, but comprises a higher doping concentration, so that an Ohmic contact can be established. In lateral direction x, y the contact region 8 may be placed in the center of the doped well 6.

In an adjacent region surrounding the doped well 6 a doped surface region 9 is arranged at the main surface 3. The doped surface region 9 forms a ring surrounding the doped well 3 in lateral directions x, y. The doped surface region 9 is in direct contact with the doped well 6. The doped surface region 9 is doped for the first type of electric conductivity. The doped surface region 9 has a doping concentration that is higher than the doping concentration of the substrate 2 and in particular higher than the doping concentration of the device layer 5.

In the transversal direction z, the doped surface region 9 is shallower than the doped well 6. This means that the doped well 6 reaches deeper into the substrate 2. In regions of the substrate 2 below the doped surface region 9 the doped well 6 can overlap the doped surface region 9 in lateral directions x, y. This means that in those regions the doped surface region 9 can be arranged above the doped well 6, as the lateral extent d, d′ of the doped well 6 can vary, as mentioned above.

Furthermore, a cover layer 10 is arranged on the main surface 3 of the substrate 2. In the embodiment shown in FIG. 1 the cover layer 10 is an epi-layer 11. The epi-layer 11 may be epitaxially grown on the semiconductor substrate 2.

Therefore, the epi-layer 11 may also comprise silicon. The epi-layer 11 is doped for the first type of electric conductivity. Its doping concentration is higher than the doping concentration of the device layer 5, but lower than the doping concentration of the doped surface region 9. The epi-layer 11 is arranged on the main surface 3 in lateral directions x, y next to the doped surface region 9. The epi-layer 11 covers the entire main surface 3 that is not covered by the doped well 6 and the doped surface region 9. However, the epi-layer 11 can also be arranged on top of the doped surface region 9 in places and/or on the upper surface 7 of the doped well 6 in places.

The embodiment shown in FIG. 1 also comprises an intermetal dielectric 12 arranged on or above the main surface 3. In places, where the epi-layer 11 is present, the intermetal dielectric 12 is arranged on the epi-layer 11. The intermetal dielectric 12 may cover the entire photodiode device 1. The intermetal dielectric 12 may comprise silicon oxide (SiO₂), for example. Within the intermetal dielectric 12 a conductor track 13 and a contact plug 14 are arranged for contacting the doped well 6. The conductor track 13 is embedded in the intermetal dielectric 12 and electrically connected to the doped well 6 via the contact plug 14. The conductor track 13 and the contact plug 14 may comprise a metal. For example, the conductor track 13 comprises aluminum (Al). The contact plug 14 can comprise tungsten (W) and/or aluminum.

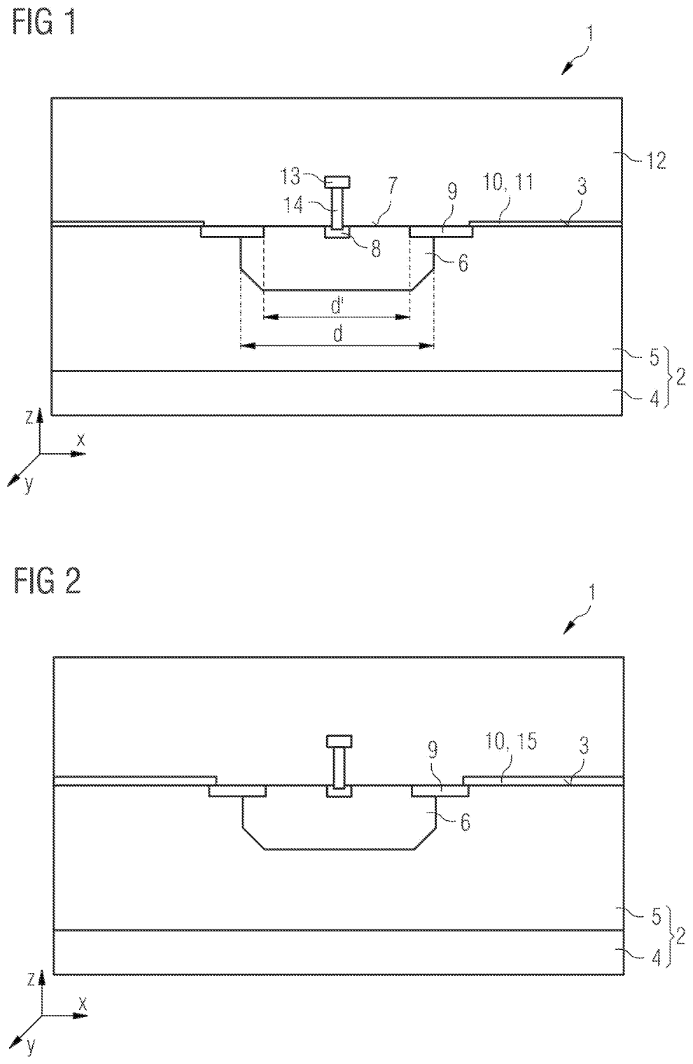

In FIG. 2 a cross section through another exemplary embodiment of the photodiode device 1 is shown. The only difference to the embodiment shown in FIG. 1 is that the cover layer 10 comprises a dielectric surface passivation layer 15 instead of the epi-layer 11. The dielectric surface passivation layer 15 comprises a plurality of space charges. The dielectric surface passivation layer 15 may comprise silicon nitride (SiN). For example, the dielectric surface passivation layer 15 comprises at least one of SiN or non-stoichiometric Si₃₊ₓN₄₋ₓ. With these materials positive space charges can be formed in the dielectric surface passivation layer 15. The dielectric surface passivation layer 15 can also comprise at least one of aluminum oxide (Al₂O₃) and hafnium oxide (HfO₂). With these materials negative space charges can be formed in the dielectric surface passivation layer 15.

Like the epi-layer 11 the dielectric surface passivation layer 15 is arranged on the main surface 3. The dielectric surface passivation layer 15 may cover the entire main surface including the upper surface 7 of the doped well 6. However, in FIG. 2 the dielectric surface passivation layer 15 only covers parts of the main surface 3 that are not covered by the doped well 6 and the doped surface region 9. As shown in FIG. 2, there might be an overlap of the doped surface region 9 and the dielectric surface passivation layer 15 in lateral directions x, y. It is possible that a native oxide film (not shown) is arranged between the main surface 3 and the dielectric surface passivation layer 15.

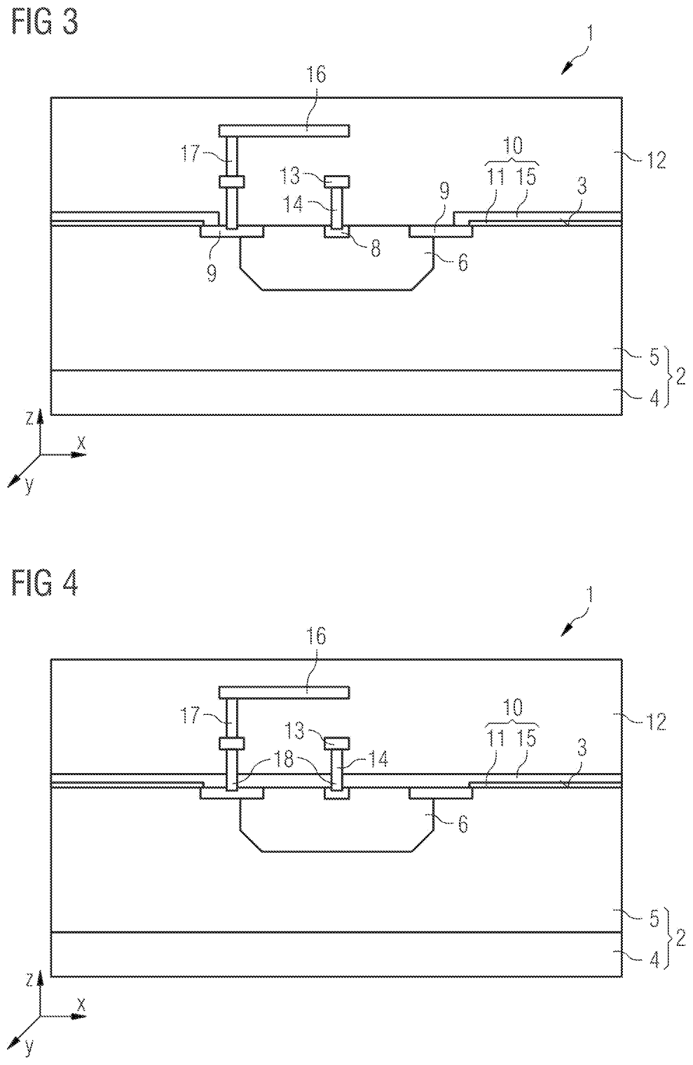

FIG. 3 shows another exemplary embodiment of the photodiode device 1. In this example, the cover layer 10 comprises a combination of the epi-layer 11 and the dielectric surface passivation layer 15. The dielectric surface passivation layer 15 is arranged on top of the epi-layer 11 at least in places. This means that in some places the cover layer 10 may be formed as a stack of both the epi-layer 11 and the dielectric surface passivation layer 15, while in other places the cover layer 10 may be formed by only one of both layers. In the example of FIG. 3 the epi-layer 11 does not cover the doped surface region 9, while the dielectric surface passivation layer 15 does cover parts of the doped surface region 9.

In places, where the cover layer 10 is present, the intermetal dielectric 12 is arranged on the cover layer 10, in particular on the dielectric surface passivation layer 15. Furthermore, FIG. 3 shows that a further conductor track 16 is embedded in the intermetal dielectric 12 and electrically connected to the substrate 2 via a further contact plug 17 and the doped surface region 9. Therefore, the doped surface region 9 can be used as contact region for the substrate 2. Like the conductor track 13 and the contact plug 14, the further conductor track 16 and the further contact plug 17 may comprise a metal. For example, the further conductor track 16 comprises aluminum. The further contact plug 17 comprises tungsten and/or aluminum. As shown on FIG. 3, the conductor track 13 and the further conductor track 16 are formed by different metallization levels. Thus, it is possible to stack the conductor track 13 and the further conductor track 16. The stacked arrangement has the advantage that the area, where incident electromagnetic radiation is blocked by the conductor track 13 and the further conductor track 16, is minimal. Furthermore, the stacked arrangement may be suitable in view of reducing the size of the photodiode device 1.

In case that the substrate 2 is p-type and the doped well 6 is n-type, an contact connecting the substrate 2 to an electric potential forms an anode terminal, while an contact connecting the doped well 6 to another electric potential forms a cathode terminal. The substrate 2 can be electrically connected to a ground potential (GND). The doped well 6 can be electrically connected to a positive potential (v+).

In FIG. 4 a cross section through another exemplary embodiment of the photodiode device 1 is shown. FIG. 4 differs from FIG. 3 is that the dielectric surface passivation layer 15 covers the entire main surface 3 including the upper surface 7 of the doped well 6. In places, where the substrate 2 and the doped well 6 is connected to the respective conductor tracks 13, 16 via contacts plugs 14, 17, the dielectric surface passivation layer 15 is provided with via holes 18 penetrating the dielectric surface passivation layer 15. Covering the entire main surface 3 by means of the dielectric surface passivation layer 15 may be advantageous in case that the dielectric surface passivation layer 15 is additionally used as anti-reflective coating. Thus, incident electromagnetic radiation is not reflected by the main surface 3 or reflection is significantly reduced.

FIG. 5 shows another embodiment of the photodiode device 1 similar to FIG. 3. However, in this embodiment no doped surface region 9 is used. Instead, the epi-layer 11 covers the main surface 3, such that it slightly overlaps the doped well 6 in lateral directions x, y. Thus, the epi-layer 11 covers a larger portion of the main surface 3 than the dielectric surface passivation 15. In the example of FIG. 5 the substrate 2 is electrically contacted via the epi-layer 11. Avoidance of the doped surface region 9 could aim to achieve high spectral responsivity in the blue wavelength range, as p+ doping induced Auger recombination at the main surface 3 is minimized and crystal damage caused by ion implantation is eliminated. Defects in the crystal lattice would offer recombination zones.

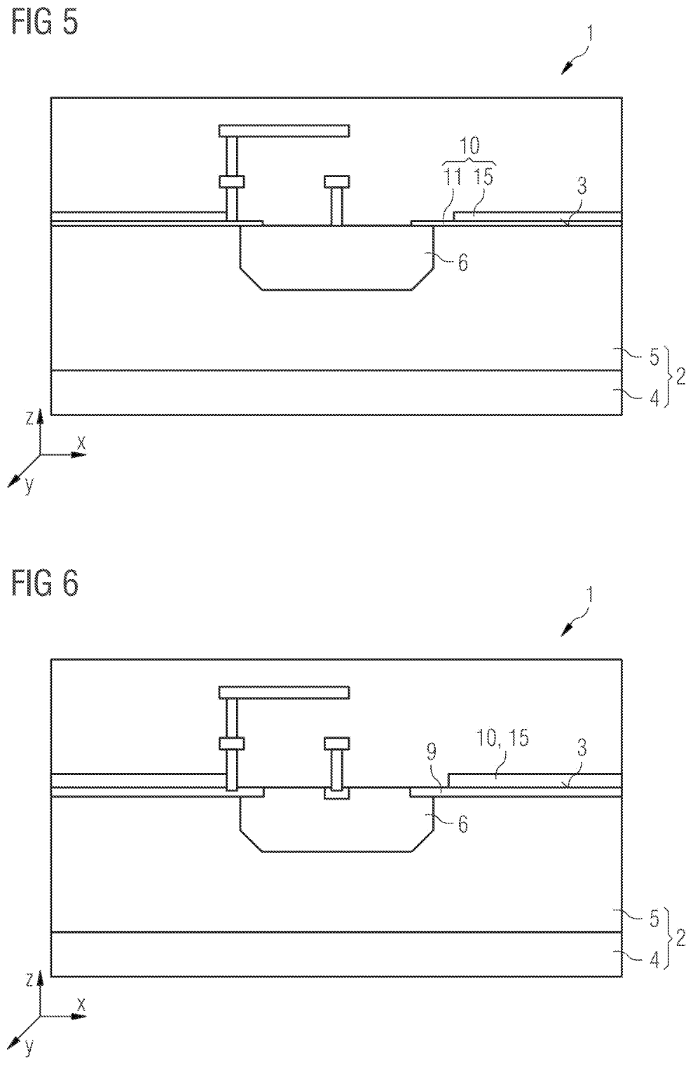

FIG. 6 shows another embodiment of the photodiode device 1. In this embodiment the cover layer 10 comprises the dielectric surface passivation layer 15, but not the epi-layer 11. The doped surface region 9 covers the entire main surface 3 apart from the doped well 6. The doped surface region 9 covers the entire main surface 3 except those portions of the main surface 3, where the doped well 6 is arranged. In this embodiment, the dielectric surface passivation layer 15 may be provided as anti-reflective coating and the doped surface region 9 may be provided for repelling charge carriers away from the main surface 3.

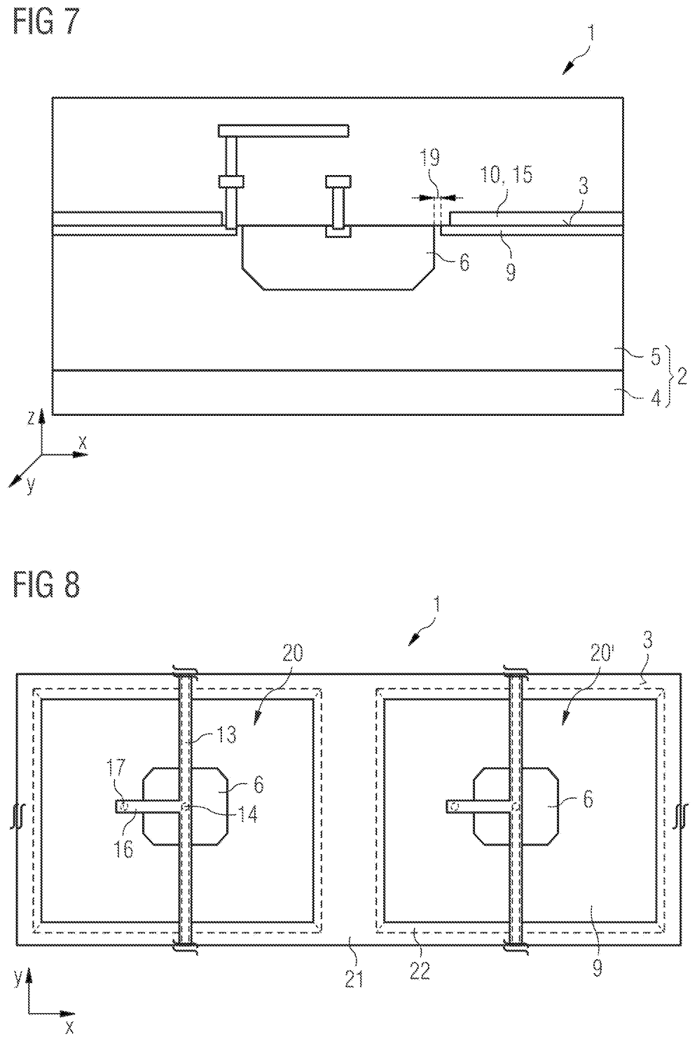

In FIG. 7 a similar embodiment as in FIG. 6 is shown. Here, there is a spacing 19 between the doped well 6 and the doped surface region 9. This means that at the main surface 3 the doped well 6 is spaced from the doped surface region 9 by the device layer 5. By means of the non-zero spacing 19 the junction capacitance between the doped well 6 and the doped surface region 9 can be reduced.

FIG. 8 shows a top-view on a further embodiment of the photodiode device 1. The photodiode device 1 comprises two pixels 20, 20′. The photodiode device 1 can comprise further pixels 20′ in each lateral direction x, y as indicated by ∫-signs. Each pixel 20, 20′ comprises an area of the main surface 3 including one doped well 6. The doped surface region 9 is adjacent to the doped well 6 and covers the entire main surface 3 comprised by said area. The cover layer 10 is omitted in FIG. 8.

The pixels 20, 20′ are separated by a trench 21, which surrounds each pixel 20, 20′ in lateral directions x, y. In other words, the trench 21 surrounds the area of the main surface 3 including the at least one doped well 6. The trench extends from the main surface 3 further into the substrate 2 than the at least one doped well 6. The trench 21 may have a taper 22 as indicated by dashed lines. This means that the trench 21 becomes narrower the deeper it reaches into the substrate 2. For example, the trench is filled with an isolating material like silicon oxide.

The conductor track 13 and the further conductor track 16 are stacked. This means that from the viewer's perspective, the conductor track 13 is not visible in FIG. 8. However, the conductor track 13 is indicated by dashes lines. Also, the contact plug 14 and the further contact plug 17 are indicated by small circles though they are not visible from the viewer's perspective.

In the embodiment shown in FIG. 8 the conductor track 13 and the further conductor track 16 run from south to north passing the center of the doped well 6. However, it is also possible, that the conductor track 13 and the further conductor track 16 are rotated and/or shifted with respect to the doped well 6. For example, the conductor track 13 and the further conductor track 16 may not cover the doped well 6. The doped well 6 can be electrically connected to the conductor track 13 by means of a branch reaching from the conductor track 13 towards a region above the doped well 6, similar to the branch of the further conductor track 16 shown in FIG. 8.

In top view, the shape of the doped wells 6 is arbitrary. FIG. 8 shows a poly-angular shape by way of example. However, circular shapes are also possible. The shape of the pixels 20, 20′ is shown to be rectangular in FIG. 8. Advantageously, rectangular pixels 20, 20′ can be combined to arrays.

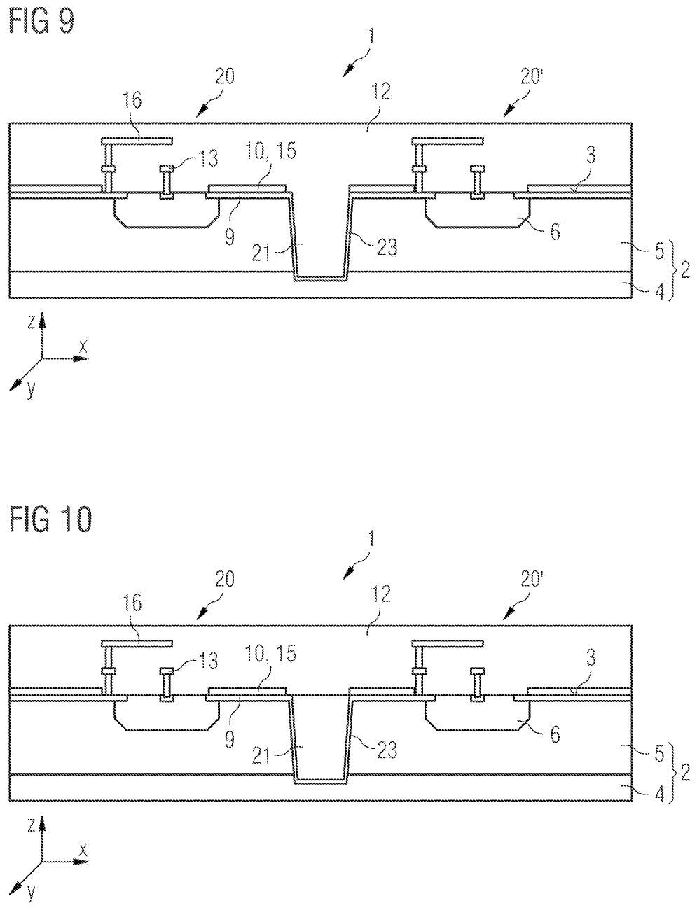

FIG. 9 shows a cross-section of the embodiment according to FIG. 8. It further shows the dielectric surface passivation layer 15 on the main surface 3 of the pixels 20, 20′. The trench 21 completely penetrates the device layer 5. The trench 21 stops in the semiconductor body 4. As shown in FIG. 9, the trench 21 tapers off towards the semiconductor body 4.

It is shown that the trench 21 can be filled with the same isolating material as the intermetal dielectric 12. However, a dopant, for example a p-type dopant, can be introduced into sidewalls 23 of the trench 21. As such, the sidewalls 23 of the trench 21 can be connected to the anode terminal via the doped surface region 9 and the further conductor track 16. Minority charge carriers are repelled from the trench 21 because of the doping gradient between the device layer 5 and the sidewalls 23 of the trench 21. Due to this mechanism photo-induced charge carriers generated in the pixel 20 cannot diffuse to another pixel 20′ and can contribute to the photocurrent. The trench 21 prevents crosstalk between neighboring pixels 20, 20′.

FIG. 10 shows a cross-section of another embodiment of the photodiode device 1. The only difference to the embodiment of FIG. 9 is that the trench 21 is filled with a doped semiconductor material. However, the trench sidewall 23 may still be doped such that its doping concentration is higher than that of the remaining filling of the trench 21. The trench 21 or the filling of the trench 21 can be electrically connected to a terminal.

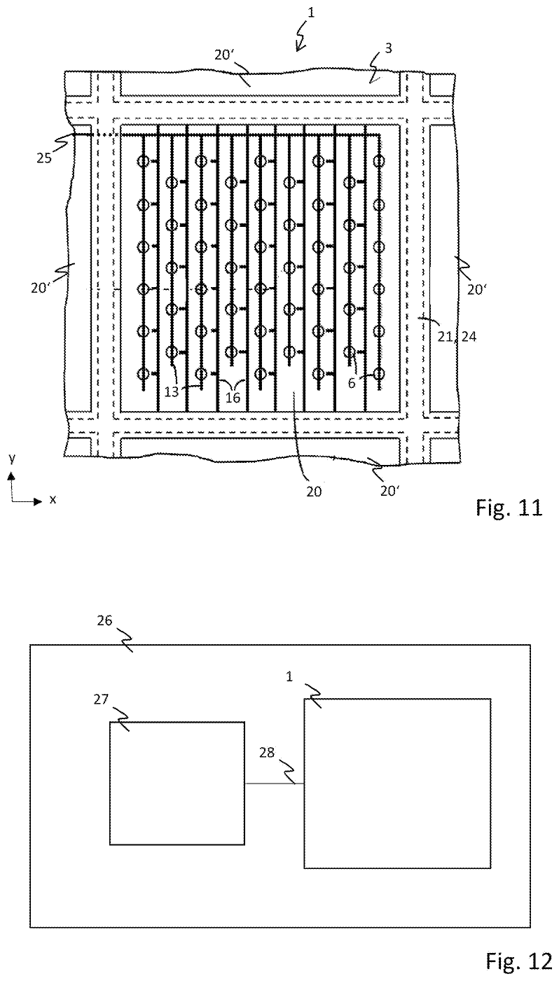

FIG. 11 is a top view of another embodiment of the photodiode device 1. It shows a plurality of doped wells 6, which are provided for one pixel 20 being part of an array of pixels 20, 20′ provided for image detection. The plurality of doped wells 6 is surrounded by the trench, which does not divide or intersect the area where the plurality of doped wells 6 is arranged. Thus, the trench 21 defines the pixel area in lateral directions x, y. Further pixels 20′ are indicated in FIG. 11 beyond the trench 21. Instead of the trench, a guard ring 24 as described above can also be used. The number of doped wells 6 is arbitrary as well as their arrangement. The arrangement shown in FIG. 11 is only an example of a suitable pattern. The distances between the doped wells 6 and their shapes can be modified and adjusted to the requirements of individual embodiments.

The doped surface region 9, the epi-layer 11 and/or the dielectric surface passivation layer 15 (said layers are omitted in FIG. 11) may cover the main surface 3 surrounded by the trench 21 or the guard ring 24 as shown in one of the previous Figures. The doped wells 6 are electrically connected by means of conductor tracks 13. Further conductor tracks 16 are arranged separate from the conductor tracks 13. The further conductor tracks 16 are electrically connected to the substrate 2. Optionally, the further conductor tracks 16 can be connected to a conductive filling of the trench 21 or to the guard ring 24, respectively. The conductor tracks 13 and the further conductor tracks 16 may be parallel and in alternating sequence, as shown in FIG. 11 by way of example. A common electric terminal 25 of the conductor tracks 13 can be connected to a control or read-out circuit (not shown) on the periphery of the array of pixels 20, 20′.

FIG. 12 shows a schematic of an optoelectronic system 26 comprising the photodiode device 1. The optoelectronic system 26 further comprises circuitry 27 for reading out electrical signals from the photodiode device 1. For example, the circuitry 27 may include storage capacitors, memory elements, an analog-to-digital converter (ADC) or the like. The circuitry 27 is electrically connected to the photodiode device 1 by means of electric interconnection 28. The optoelectronic system 26 can be, for example, a camera system or an electromagnetic radiation sensor, especially for ambient light. The optoelectronic system 26 can be used for applications in the automotive, the industrial, the scientific and the medical field. Moreover, it can also be employed in consumer electronics.

The embodiments of the photodiode device disclosed herein have been discussed for the purpose of familiarizing the reader with novel aspects of the idea. Although preferred embodiments have been shown and described, many changes, modifications, equivalents and substitutions of the disclosed concepts may be made by one having skill in the art without unnecessarily departing from the scope of the claims.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art and fall within the scope of the appended claims.

The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

1. A photodiode device, comprising:
a semiconductor substrate with a main surface, the semiconductor substrate being of a first type of electric conductivity, wherein the substrate comprises a semiconductor body and a device layer arranged on the semiconductor body, such that the main surface is formed by a surface of the device layer,
at least one doped well of a second type of electric conductivity at the main surface of the substrate, the second type of electric conductivity being opposite to the first type of electric conductivity, wherein an upper surface of the doped well forms a part of the main surface of the substrate, wherein the at least one doped well and the substrate are electrically contactable,
a cover layer being arranged on the main surface of the substrate at least in places outside the doped well, wherein the cover layer comprises an epi-layer of the first type of electric conductivity, the epi-layer forms an interface with the device layer, a doping concentration of the epi-layer is higher than a doping concentration of the device layer, and wherein the epi-layer is arranged such that in a transversal direction a region above the at least one doped well is free from the epi-layer, wherein the transversal direction runs perpendicular to the main surface of the substrate.

2. (canceled)

3. The photodiode device according to claim 1, wherein the epi-layer is in-situ doped for the first type of electric conductivity, such that it has a doping concentration that is higher than a doping concentration of the device layer.

4. The photodiode device according to claim 1, wherein the epi-layer has a thickness being at most 100 nm, at most 50 nm, or at most 10 nm.

5. (canceled)

6. (canceled)

7. (canceled)

8. The photodiode device according to claim 1, wherein the cover layer is provided for repelling charge carriers and/or for use as anti-reflective coating.

9. The photodiode device according to claim 1, further comprising at least one doped surface region of the first type of electric conductivity at the main surface of the substrate, wherein the at least one doped well is free from the doped surface region.

10. The photodiode device according to claim 9, wherein in lateral directions, which run parallel to the main surface of the substrate, there is a spacing between the at least one doped well and the at least one doped surface region.

11. The photodiode device according claim 9, wherein in lateral directions the at least one doped surface region forms a ring or a frame surrounding the at least one doped well.

12. The photodiode device according to claim 1, further comprising
an intermetal dielectric arranged on or above the main surface of the substrate, a conductor track embedded in the intermetal dielectric and electrically connected to the at least one doped well, and
a further conductor track embedded in the intermetal dielectric and electrically connected to the substrate.

13. The photodiode device according to claim 1, further comprising a trench extending from the main surface further into the substrate than the at least one doped well and surrounding an area of the main surface including the at least one doped well.

14. The photodiode device according to claim 13, wherein the trench is at least partially filled with a doped semiconductor material or an electrically insulating material.

15. The photodiode device according to claim 12, wherein the at least one doped well is comprised by one pixel of an array of pixels of the photodiode device, the pixels being separated by the trench.

16. An optoelectronic system comprising the photodiode device according to claim 1, wherein the optoelectronic system is provided for detection of electromagnetic radiation, in particular ambient light detection.

17. A photodiode device, comprising:
a semiconductor substrate with a main surface, the semiconductor substrate being of a first type of electric conductivity,
at least one doped well of a second type of electric conductivity at the main surface of the substrate, the second type of electric conductivity being opposite to the first type of electric conductivity, wherein an upper surface of the doped well forms a part of the main surface of the substrate, wherein the at least one doped well and the substrate are electrically contactable, and
a cover layer being arranged on the main surface of the substrate at least in places outside the doped well, wherein the cover layer comprises a dielectric surface passivation layer comprising aluminum oxide and/or hafnium oxide and comprising a plurality of negative space charges, such that an electric field is established at the main surface of the substrate.

18. The photodiode device according to claim 17, wherein the cover layer is provided for repelling charge carriers and/or for use as anti-reflective coating.

19. The photodiode device according to claim 17, further comprising at least one doped surface region of the first type of electric conductivity at the main surface of the substrate, wherein the at least one doped well is free from the doped surface region.

20. The photodiode device according to claim 19, wherein in lateral directions, which run parallel to the main surface of the substrate, there is a spacing between the at least one doped well and the at least one doped surface region.

21. The photodiode device according to claim 19, wherein in lateral directions the at least one doped surface region forms a ring or a frame surrounding the at least one doped well.

22. An optoelectronic system comprising the photodiode device according to claim 17, wherein the optoelectronic system is provided for detection of electromagnetic radiation, in particular ambient light detection.
